(19) United States
(12) Patent Application Publication
(10) Pub. No.: US 2005/0083441 A1
(43) Pub. Date: Apr. 21, 2005

(54) Tuner for receiving digital broadcast

(76) Inventors: Hisashi Fujiwara, Akita (JP); Masayuki Hosoi, Saitama (JP)

Correspondence Address: FROMMER LAWRENCE & HAUG LLP, 745 FIFTH AVENUE, NEW YORK, NY, 10151, US

(21) Appl. No.: 10/926,169

(22) Filed: Aug. 25, 2004

(30) Foreign Application Priority Data
Aug. 27, 2003 (JP) 2003-209095
Jul. 6, 2004 (JP) 2004-199600

(51) Int. Cl. H04N 7/173; H04N 7/16; H03L 7/00; H04N 5/50

(52) U.S. Cl. 348/731; 725/100; 725/131; 725/151; 348/732

(57) ABSTRACT

A tuner for receiving a digital broadcast is disclosed which prevents application of an unexpected excessively high voltage to a power supply pin or the like upon inspection or adjustment or after it is assembled into a set. The digital broadcast receiving tuner includes a channel selection section, a demodulation section, and a plurality of terminal pins electrically connected to the channel selection section and the demodulation section and including a power supply pin. The terminal pins further include a grounding pin disposed on at least one side of the power supply pin.

### BACKGROUND OF THE INVENTION

This invention relates to a tuner for receiving a digital broadcast.

Conventionally, various tuners for receiving a BS digital broadcast have been proposed, and one of such tuners is shown in FIGS. 4 and 5. FIG. 5 shows an appearance of the BS digital broadcast receiving tuner. Referring to FIG. 5, the BS digital broadcast receiving tuner shown includes a shield case 1 in which, for example, such a tuner circuit as shown in FIG. 4 is provided.

Referring to FIG. 4, the tuner circuit shown includes an input terminal 2 to which a BS digital broadcast signal received by a BS antenna or the like is supplied. The BS digital broadcast signal obtained at the input terminal 2 is supplied to a variable attenuator 4 through an amplification circuit 3. For example, a dc power supply of 5 V supplied to a power supply pin 1a is supplied as a power supply to the amplification circuit 3.

The variable attenuator 4 is controlled in accordance with the signal level obtained at a QPSK/8PSK demodulation circuit 5 hereinafter described so that the signal level obtained at the output side of the variable attenuator 4 may be fixed.

An output signal of the variable attenuator 4 is supplied to a variable gain amplification circuit 6b, which forms an automatic gain control circuit, through an amplification circuit 6a of a Zero-IF QPSK/8PSK down converter 6 which forms channel selection-means. The variable gain amplification circuit 6b is controlled in gain in accordance with a gain control signal from a gain control signal production circuit 6c, which produces a gain control signal in response to the signal level obtained at the QPSK/8PSK demodulation circuit 5.

An output signal of the variable gain amplification circuit 6b is supplied to one of input terminals of each of multiplication circuits 6d and 6e.

The tuner circuit further includes a local oscillation circuit 7 formed from a PLL circuit and including a variable frequency oscillation circuit 7a for controlling the capacitance of a variable capacitor to vary the oscillation frequency of the local oscillation circuit 7. An oscillation signal of the variable frequency oscillation circuit 7a is supplied to one of input terminals of a comparison circuit 7b while a channel selection signal obtained at a terminal pin 1f is supplied to the other input terminal of the comparison circuit 7b.

An error signal obtained by the comparison circuit 7b is supplied to a low-pass filter 7c. The low-pass filter 7c adds a dc voltage of the error signal and a dc voltage of, for example, 32 V supplied to a power supply pin 1c to obtain a tuning voltage and supplies the tuning voltage to the variable capacitor of the variable frequency oscillation circuit 7a.

The oscillation signal of the variable frequency oscillation circuit 7a is supplied to the other input terminal of the multiplication circuit 6d. Further, the oscillation signal of the variable frequency oscillation circuit 7a is supplied to the other input terminal of the multiplication circuit 6e through a 90° phase-shift circuit 6f.

An I signal obtained on the output side of the multiplication circuit 6d is supplied to the QPSK/8PSK demodulation circuit 5 formed from a semiconductor integrated circuit through a series circuit of the low-pass filter 6g and an amplification circuit 6h. Further, a Q signal obtained on the output side of the multiplication circuit 6e is supplied to the QPSK/8PSK demodulation circuit 5 through another series circuit of a low-pass filter 6i and an amplification circuit 6j. A transport stream packet obtained on the output side of the QPSK/8PSK demodulation circuit 5 is supplied to a back end circuit from eight output terminal pins 1g.

Further, a stable dc power supply of, for example, 5 V obtained at the power supply pin 1b is supplied as a power supply to the Zero-IF QPSK/8PSK down converter 6 and the local oscillation circuit 7.

To the QPSK/8PSK demodulation circuit 5 formed from a semiconductor integrated circuit, dc power supplies of, for example, 1.5 V and 3.3 V obtained at the power supply pins 1d and 1e, respectively, are supplied as power supplies.

The power supply pins 1a, 1b, . . . , 1e of the conventional BS digital broadcast receiving tuner are arranged in a mutually adjacent juxtaposed relationship as seen in FIG. 5.

The BS digital broadcast receiving tuner further includes, in addition to the terminal pins mentioned hereinabove, terminal pins for synchronizing signals, terminal pins for clock signals, terminal pins for an error indicator and so forth. Thus, the BS digital broadcast receiving tuner includes totally approximately 30 terminal pins.

Incidentally, miniaturization is demanded also for a BS digital broadcast receiving tuner. However, miniaturization of the conventional BS digital broadcast receiving tuner is difficult because a distance of 2.54 mm is required between adjacent ones of the approximately 30 terminal pins.

Thus, it is a possible idea to set the distance between adjacent ones of such approximately 30 terminal pins to a comparatively small distance such as, for example, to 2 mm to achieve miniaturization of the BS digital broadcast receiving tuner while the power supply pins 1a, 1b, . . . , 1e are arranged in a juxtaposed relationship as in the conventional BS digital broadcast receiving tuner.

In this instance, since the distance between adjacent ones of the power supply pins 1a, 1b, . . . , 1e is comparatively small such as, for example, 2 mm, there is the possibility that, upon inspection or adjustment in manufacture of the BS digital broadcast receiving tuner, for example, a check pin for supplying a dc power supply of 32 V or a like pin may contact not only with the power supply pin 1c but also with the adjacent power supply pin 1b or 1d. If the check pin contacts with the power supply pin 1b or 1d in error, then an unexpected excessively high voltage is supplied to the power supply pin 1b or 1d. The BS digital broadcast receiving tuner cannot take a sufficient countermeasure for protection against the inrush of the excessively high voltage, and disadvantageously there is the possibility that the BS digital broadcast receiving tuner may suffer from breakdown of an internal part thereof.

Further, when such a BS digital broadcast receiving tuner as described above is assembled into a set, the terminal pins are inserted into, a main board of the set and soldered to the main board using a solder tank. Thereupon, since the distance between adjacent ones of the power supply pins 1a, 1b, . . . , 1e is comparatively small, a solder bridge is likely to appear. If a solder bridge is produced between, for example, the power supply pin 1c for supplying a dc power supply of 32 V and the power supply pin 1b or 1d, then even if the BS digital broadcast receiving tuner is normal before it is assembled, disadvantageously there is the possibility that an unexpected excessively high voltage may rush into the BS digital broadcast receiving tuner to give rise to a breakdown of an internal part of the BS digital broadcast receiving tuner or to a breakdown of the set in which the BS digital broadcast receiving tuner is assembled.

In this instance, since the BS digital broadcast receiving tuner before the incorporation is normal, disadvantageously it is comparatively difficult to find out a cause of the failure.

### SUMMARY OF THE INVENTION

It is an object of the present invention to provide a tuner for receiving a digital broadcast which prevents application of an unexpected excessively high voltage to a power supply pin or the like thereof upon inspection or adjustment or after it is assembled into a set.

In order to attain the object described above, according to an aspect of the present invention, there is provided a tuner for receiving a digital broadcast, comprising channel selection means, demodulation means, and a plurality of terminal pins electrically connected to the channel selection means and the demodulation means and including a power supply pin and a grounding pin disposed on at least one side of the power supply pin.

With the tuner for receiving a digital broadcast, since the grounding pin is disposed on at least one side of the power supply pin, an adjacent pin to the power supply pin is the grounding pin, and a pin with or to which a check pin or the like to which a power supply of, for example, 32 V is supplied is contacted in error or bridged by solder upon inspection or adjustment or after the digital broadcast receiving tuner is assembled into a set is the grounding pin. Consequently, the possibility that an unexpected voltage may be applied to the other pins can be eliminated. In this instance, even if a high voltage of, for example, 32 V is applied to the grounding pin in error, there is no possibility that it may break down a part of the digital broadcast receiving tuner or an apparatus connected to the tuner.

According to another aspect of the present invention, there is provided a tuner for receiving a digital broadcast, comprising channel selection means, demodulation means, and a plurality of terminal pins electrically connected to the channel selection means and the demodulation means and including a plurality of power supply pins for supplying a plurality of powers of voltages different from each other and a pair of grounding pins disposed on the opposite sides of that one of the power supply pins which is for the power supply of the highest one of the different voltages.

With the tuner for receiving a digital broadcast, the grounding pins are disposed on the opposite sides of the power supply pin to which the highest power supply voltage is applied. Consequently, similar advantages to those described above are achieved.

The above and other objects, features and advantages of the present invention will become apparent from the following description and the appended claims, taken in conjunction with the accompanying drawings in which like parts or elements denoted by like reference symbols.

### BRIEF DESCRIPTION OF THE DRAWINGS

FIG. 1 is a block diagram showing a tuner for receiving a digital broadcast to which the present invention is applied;

FIG. 2 is a side elevational view showing an appearance of the digital broadcast receiving tuner of FIG. 1;

FIG. 3 is a top plan view showing an appearance of the digital broadcast receiving tuner of FIG. 1;

FIG. 4 is a block diagram showing an example of conventional tuner for receiving a digital broadcast; and

FIG. 5 is a plan view showing an appearance of the conventional digital broadcast tuner of FIG. 4.

### DESCRIPTION OF THE PREFERRED EMBODIMENT

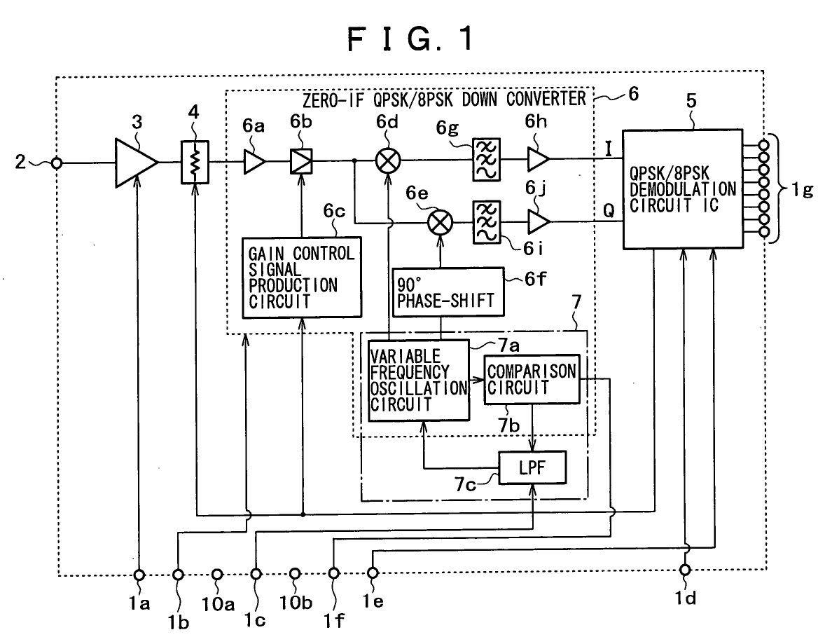

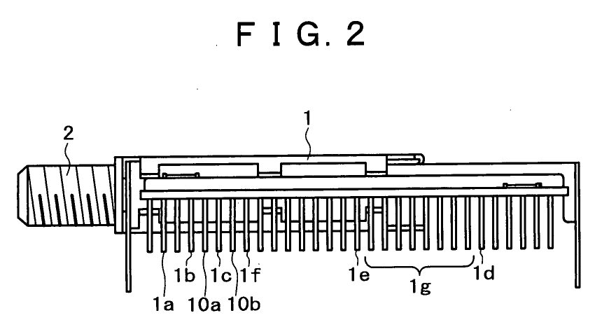

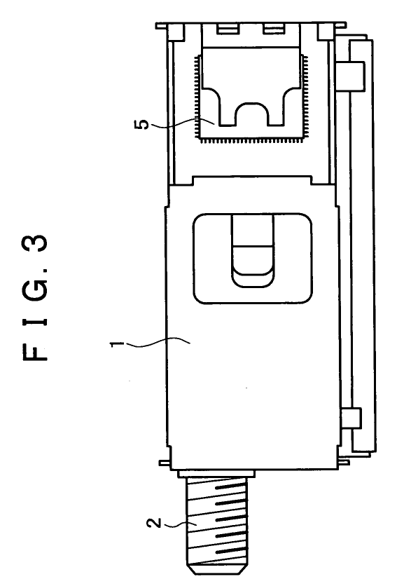

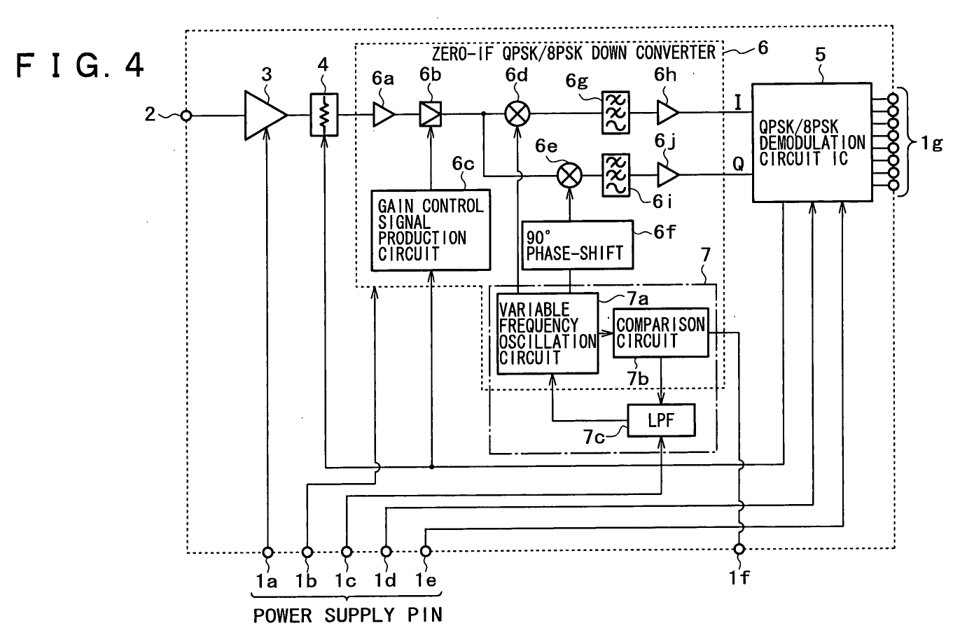

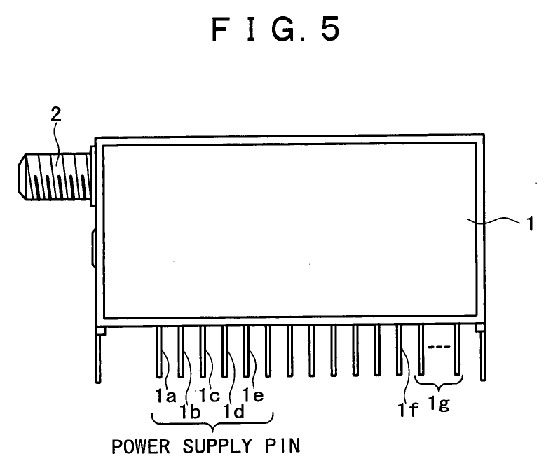

FIGS. 1, 2 and 3 show a tuner for receiving a digital broadcast to which the present invention is applied. Of the reference characters in FIGS. 1, 2 and 3, those already used in FIGS. 4 and 5 designate like or corresponding parts. FIGS. 2 and 3 show side and top appearances of the BS digital broadcast receiving tuner and show a shield case 1 in which a tuner circuit for receiving a BS digital broadcast similar to that of FIG. 4 is provided.

Referring to FIG. 1, a BS digital broadcast signal received by a BS antenna or the like is supplied to an input terminal 2. The BS digital broadcast signal obtained at the input terminal 2 is supplied to a variable attenuator 4 through an amplification circuit 3. For example, a dc power supply of 5 V supplied to a power supply pin 1a is supplied as a power supply to the amplification circuit 3.

The variable attenuator 4 is controlled in accordance with the signal level obtained at a QPSK/8PSK demodulation circuit 5 hereinafter described so that the signal level obtained at the output side of the variable attenuator 4 may be fixed.

An output signal of the variable attenuator 4 is supplied to a variable gain amplification circuit 6b, which forms an automatic gain control circuit, through an amplification circuit 6a of a Zero-IF QPSK/8PSK down converter 6 which forms channel selection means. The variable gain amplification circuit 6b is controlled in gain in accordance with a gain control signal from a gain control signal production circuit 6c, which produces a gain control signal in response to the signal level obtained at the QPSK/8PSK demodulation circuit 5.

An output signal of the variable gain amplification circuit 6b is supplied to one of input terminals of each of multiplication circuits 6d and 6e.

The tuner circuit further includes a local oscillation circuit 7 formed from a PLL circuit and including a variable frequency oscillation circuit 7a for controlling the capacitance of a variable capacitor to vary the oscillation frequency of the local oscillation circuit 7. An oscillation signal of the variable frequency oscillation circuit 7a is supplied to one of input terminals of a comparison circuit 7b while a channel selection signal obtained at a terminal pin 1f is supplied to the other input terminal of the comparison circuit 7b.

An error signal obtained by the comparison circuit 7b is supplied to a low-pass filter 7c. The low-pass filter 7c adds a dc voltage of the error signal and a dc voltage of, for example, 32 V supplied to a power supply pin 1c to obtain a tuning voltage and supplies the tuning voltage to the variable capacitor of the variable frequency oscillation circuit 7a.

The oscillation signal of the variable frequency oscillation circuit 7a is supplied to the other input terminal of the multiplication circuit 6d. Further, the oscillation signal of the variable frequency oscillation circuit 7a is supplied to the other input terminal of the multiplication circuit 6e through a 90° phase-shift circuit 6f.

An I signal obtained on the output side of the multiplication circuit 6d is supplied to the QPSK/8PSK demodulation circuit 5 formed from a semiconductor integrated circuit through a series circuit of the low-pass filter 6g and an amplification circuit 6h. Further, a Q signal obtained on the output side of the multiplication circuit 6e is supplied to the QPSK/8PSK demodulation circuit 5 through another series circuit of a low-pass filter 6i and an amplification circuit 6j. A transport stream packet obtained on the output side of the QPSK/8PSK demodulation circuit 5 is supplied to a back end circuit from eight output terminal pins 1g.

Further, a stable dc power supply of, for example, 5 V obtained at the power supply pin 1b is supplied as a power supply to the Zero-IF QPSK/8PSK down converter 6 and the local oscillation circuit 7.

To the QPSK/8PSK demodulation circuit 5 formed from a semiconductor integrated circuit, dc power supplies of, for example, 1.5 V and 3.3 V obtained at the power supply pins 1d and 1e, respectively, are supplied as power supplies.

In the present embodiment, a predetermined number of, for example, 30, terminal pins including the power supply pins 1a, 1b, . . . , 1e, output terminal pins 1g and terminal pin 1f of the BS digital broadcast receiving tuner are provided at equal distances as shown in FIG. 2.

In the present embodiment, grounding pins 10a and 10b connected to the ground of the BS digital broadcast receiving tuner are disposed between the power supply pin 1b and the power supply pin 1c and between the power supply pin 1c and the terminal pin 1f, respectively.

Incidentally, from among the 30 terminal pins of the BS digital broadcast receiving tuner shown in FIG. 2 according to the present embodiment, the first terminal pin from the left side in FIG. 2 is a free pin connected to no circuit element.

The second terminal pin is the power supply pin 1a to which a dc power supply of, for example, 5 V is supplied. The third terminal pin is a low noise blocking power supply pin. The fourth terminal pin is the power supply pin 1b to which a stable dc power supply of, for example, 5 V is supplied. The fifth terminal pin is the grounding pin 10a connected to the ground. The sixth terminal is the power supply pin 1c to which a maximum dc voltage of, for example, 32 V is supplied. The seventh terminal pin is the grounding pin 10b connected to the ground.

The eighth terminal pin is the terminal pin 1f to which a channel selection signal is supplied. The ninth terminal pin is a terminal pin to which an address selection signal for a demodulation IC is supplied. The tenth terminal pin is a terminal pin to which a hard reset signal is supplied. The eleventh and twelfth terminal pins are terminal pins to which an interface is connected. The thirteenth terminal pin is a terminal pin to which an activation control signal in a TMCC signal is outputted.

The fourteenth terminal pin is a terminal pin from which a change instruction signal in the TMCC signal is outputted. The fifteenth terminal pin is a terminal pin from which a frame synchronizing signal is outputted. The sixteenth terminal pin is the power supply pin 1e to which a dc voltage of, for example, 3.3 V is supplied. The seventeenth to twenty-fourth terminals are the output terminal pins 1g for a transport stream packet.

The twenty-fifth terminal pin is the power supply pin 1d to which a dc voltage of, for example, 1.5 V is supplied. The twenty-sixth terminal pin is a terminal pin from which a transport stream clock is outputted. The twenty-seventh terminal pin is a terminal pin for a synchronizing signal for transport stream data. The twenty-eighth terminal pin is an enable terminal pin for transport stream data. The twenty-ninth terminal pin is a terminal for a synchronizing signal for a transport stream data super frame. The thirtieth terminal pin is a terminal pin for connection of an error indicator.

In the present embodiment, since the grounding pins 10a and 10b connected to the ground are disposed between the power supply pins 1b and 1c and between the power supply pin 1c and the next terminal pin 1f, respectively, for example, adjacent pins to the power supply pin 1c to which the power supply of 32 V is supplied are the grounding pins 10a and 10b. Thus, a pin with which a check pin or the like to which, for example, a power supply of 32 V is supplied upon inspection or adjustment may contact in error is the grounding pin 10a or 10b. Further, a pin to which the power supply pin 1c is bridged by solder when the BS digital broadcast receiving tuner is assembled into a set is the grounding pin 10a or 10b. Thus, an unexpected excessively high voltage is not applied to the other power supply pins 1b and 1d at all.

In this instance, even if a high voltage of, for example, 32 V is applied in error to the grounding pin 10a or 10b, there is no possibility that the high voltage may break down a part in the BS digital broadcast receiving tuner or the set in which the BS digital broadcast receiving tuner is assembled.

Accordingly, with the embodiment described above, the distance between adjacent ones of the terminal pins can be reduced and the BS digital broadcast receiving tuner can be miniaturized with safety.

While a preferred embodiment of the present invention has been described using specific terms, such description is for illustrative purposes only, and it is to be understood that changes and variations may be made without departing from the spirit or scope of the following claims.

1. A tuner for receiving a digital broadcast, comprising:
channel selection means;
demodulation means; and
a plurality of terminal pins electrically connected to said channel selection means and said demodulation means and including a power supply pin and a grounding pin disposed on at least one side of said power supply pin.

2. A tuner for receiving a digital broadcast, comprising:
channel selection means;
demodulation means; and
a plurality of terminal pins electrically connected to said channel selection means and said demodulation means and including a plurality of power supply pins for supplying a plurality of powers of voltages different from each other and a pair of grounding pins disposed on the opposite sides of that one of said power supply pins which is for the power supply of the highest one of the different voltages.
